(19) United States
(12) Patent Application Publication
(10) Pub. No.: US 2011/0171816 A1
(43) Pub. Date: Jul. 14, 2011

(54) SYNTHESIS OF GERMANIUM SULFIDE AND RELATED COMPOUNDS FOR SOLID ELECTROLYTIC MEMORY ELEMENTS AND OTHER APPLICATIONS

(75) Inventors: Gary S. Tompa, Belle Mead, NJ (US); Elane Coleman, Somerset, NJ (US); Lloyd G. Provost, Glen Ridge, NJ (US)

(73) Assignee: Structured Materials Inc., Piscataway, NJ (US)

(21) Appl. No.: 12/761,957

(22) Filed: Apr. 16, 2010

Related U.S. Application Data
(63) Continuation-in-part of application No. PCT/US2008/011874, filed on Oct. 18, 2008.
(60) Provisional application No. 60/999,486, filed on Oct. 18, 2007.

(51) Int. Cl. H01L 21/20; H01L 21/31

(52) U.S. Cl. 438/508; 438/478; 438/758; 257/E21.09; 257/E21.24

(57) ABSTRACT

A method for making high purity GeS and related compounds such as Germanium Silicon Sulfide (GeSiS); Copper Sulfide (CuS); Silicon Sulfide (SiS); Zinc Sulfide (ZnS) and Iron Sulfide (FeS) at low temperatures and pressures in a Chemical Vapor Deposition (CVD) process for solid electrolyte memory elements and other applications. Disclosed is a method of generating a proper chemical and energy environment for the formation of GeS and related compounds on a specific surface. The produced films have utility in memory and other devices. The technology offers cost savings and the advantage of low temperature film creation through the use of plasma assisted deposition—increasing its compatibility for use not only on silicon (or ceramic or glass) non metal substrates as well as polymer or thin metal foil substrates which would be damaged by higher temperature processes.

### REFERENCE TO RELATED APPLICATIONS

This application is a continuation in part of and claims priority of PCT Patent Application PCT/US08/11874 filed on Oct. 18, 2008 which in turn claims priority of U.S. Provisional Patent application Ser. No. 60/999,486 filed on Oct. 18, 2007 and titled “Electrolytic Film Deposition Process and Tool”. The disclosures of these applications are hereby incorporated by reference.

This application also incorporates by reference U.S. patent application Ser. No. 12/157,057 filed on Jun. 6, 2008 and titled “Method of Making Undoped, Alloyed and Doped Chalcogenide Films by MOCVD Processes”.

### STATEMENT OF GOVERNMENT SUPPORT OF THE INVENTION

The work leading to this invention was supported, in part, by the US Missile Defense Agency under contact No. HQ0006-07-C-7769.

### BACKGROUND OF THE INVENTION

This invention relates to synthesis of Germanium Sulfide (GeS) and related compounds such as Germanium Silicon Sulfide (GeSiS); Copper Sulfide (CuS); Silicon Sulfide (SiS); Zinc Sulfide (ZnS) and Iron Sulfide (FeS) for solid electrolytic memory elements, programmable metal cells, memristors, and other electronic applications, such devices have particular applicability to applications requiring radiation hardness.

Of high importance for various computing applications for aerospace and military components are memory devices that are nonvolatile, i.e. retain their memory state when no power is applied, and retain their memory state in a radiation environment. Under these conditions, nonvolatile memory devices based on standard silicon technology are prone to Single Event Upsets (SEU) and “latch up” failures. Typically, these failures become more prominent with increasing memory density. Materials systems other than silicon or in combination with silicon offer significant advantages to ensure cost effectiveness and to ensure that high-density memory products can result. Leveraging silicon manufacturing technology will ensure low unit cost and benefit from established architectures that are reliable in performance and have the ability to be plug-in replacements. The present invention is an important stepping stone to a plug-in replacement nonvolatile memory based on Solid Electrolyte films, and demonstrates basic cell functionality of Ag—Ge—S films produced by Metal Organic Chemical Vapor Deposition (MOCVD)—including derivatives of this technique such as plasma enhanced CVD, Precursor Pulsing CVD, and Plasma and Precursor Pulsing CVD, which is anticipated to be needed to produce films in multi-Gigabit architectures. The Plasma and Precursor Pulsing CVD is different than simpler alternating layer deposition approaches because it allows for some layers to be deposited with an activator, such as the plasma, and then other layers to be deposited without the plasma but then to be treated (exposed) to a plasma before another layer is applied—this approach adds great versatility to the way in which deposited films can be built up.

This work will also significantly advance radiation-hardened electronic technology since solid electrolytes are inherently radiation hard. The technology is applicable to radiation hardened nonvolatile memory for both military and aerospace markets as well as commercial products. Solid electrolyte technology has been demonstrated as low voltage, high speed, nonvolatile memory. In addition to radiation hard needs, memory in general, field programmable gate arrays and other variable state dependent devices can benefit from improved manufacturability of advanced materials,

This work builds upon previous efforts based on Physical Vapor Deposition (PVD), or commonly called sputtering, which needs to be advanced in order to enable high density scaling. Solid electrolyte memories are projected to scale to ultra-high densities (>16 Gbyte) that surpass the capability of silicon technology while using similar cell areas. Emerging technologies such as solid electrolytes do not use charge tunneling as the storage mechanism but instead use nanoscale physical properties. Such a material system offers the important advantage that it is not prone to electronic breakdown failure at scaled down geometries and is inherently resistant to adverse ionizing effects of radiation that create threshold changes in the memory cell. Further, solid electrolytes are fast (read write cycle <50 ms) and operate at 1 volt. These features make solid electrolytes highly attractive as a radiation hardened memory as well as a potential replacement for silicon-based memory devices.

Due to the extremely small memory cell areas of solid electrolyte (as small as in the range 10 nm×10 nm) memory devices, there is a real and significant need for developing supporting manufacturing and process technology. Sputtering is unlikely to assure the required defect density for mass memory scaled electrolytes. Currently the needed capabilities for manufacturing do not exist outside the laboratory and will have to be developed for the potential of high-density solid electrolyte nonvolatile memory to be realized. Accordingly there is a need to supplant sputtering with MOCVD. Since standard silicon memory technology is projected to scale below 90 nm before a replacement technology will be required for commercial nonvolatile memory products, MOCVD will be the manufacturing technique employed as it is scalable to these geometries due to its ability to deposit contiguous pin-hole free films and the much needed capability to fill small high aspect ratio holes for the active material. MOCVD and Pulsed Precursor Deposition (PPD) are of course also very useful for planar topographies as well.

This invention addresses the making of high purity GeS and related compounds such as Germanium Silicon Sulfide (GeSiS); Copper Sulfide (CuS); Silicon Sulfide (SiS); Zinc Sulfide (ZnS) and Iron Sulfide (FeS) at low temperatures and pressures in a Chemical Vapor Deposition (CVD) and a Pulsed Precursor Deposition (PPD) process for solid electrolyte memory elements and other applications. The ZnS and FeS may also be used for photovoltaics and other applications. Disclosed is a method of generating a proper chemical and energy environment for the formation of GeS and related compounds on a specific surface. The produced films have great utility in memory and other devices. The invented technology offers great cost saving and advantage of low temperature film creation when using plasma assisted deposition—increasing its compatibility for use not only on silicon or other ceramic substrates but also for use on metal, metal foil, or polymer substrates; the later two which would be damaged by higher temperature processes.

MOCVD Metalorganic Chemical Vapor Deposition is a well-established manufacturing technology that has a demonstrated capability of uniformly fabricating thin films of high quality and excellent conformality integrated circuit device layers at a high throughput rate. However, until now MOCVD has not been applied successfully to the fabrication of GeS films. Importantly, MOCVD also offers the opportunity to easily vary the alloy composition of the GeS layer which should further improve endurance and other device characteristics. In addition, MOCVD has an advantage over sputtering for tuning of the film in that it offers run-to-run tuning of composition through flow control as compared to the need to purchase new targets and to re-setup and qualify the tool for sputtering; thus greatly speeding the process and reducing the cost. MOCVD can also functionally grade layer composition by varying the constituent precursor concentration throughout the deposition process. The process can utilize gaseous, liquid and solid precursors for the germanium, sulfur and dopant or alloy constituents.

### BRIEF DESCRIPTION OF THE DRAWINGS

For a better understanding of the invention, reference is made to the following drawings which are to be taken in conjunction with the detailed description to follow in which:

FIG. 1 is a schematic representation of a CVD deposition system suitable for carrying out the present invention;

FIG. 2 is an X-Ray Flourescence (XRF) plot showing the deposited GeS films produced by elemental S and GeH₄ precursors;

FIG. 3 is a Secondary Ion Mass Spectroscopy (SIMS) depth profile of GeS films grown with H₂S and GeH₄ precursors;

FIG. 4 is a SIMS depth profile of GeS films grown with elemental S and GeH₄.

FIG. 5 is a current (left) and resistance (right) hysteresis (writing) plot of a lateral device test structure produced by the present methodology on un-metalized polymer (Kapton™);

FIGS. 6 through 10 are spreadsheets showing the procedures for the deposition of Germanium Sulfide (GeS); Germanium Silicon Sulfide (GeSiS); Copper Sulfide (CuS); Silicon Sulfide (SiS); Zinc Sulfide (ZnS) and Iron Sulfide (FeS) by CVD (and PPD) in accordance with the present invention;

FIG. 11 is a spreadsheet showing the procedure for the deposition of Germanium Silicon Sulfide (GeSiS) in alternating layers.

### DESCRIPTION OF THE PREFERRED EMBODIMENTS

### MOCVD Equipment

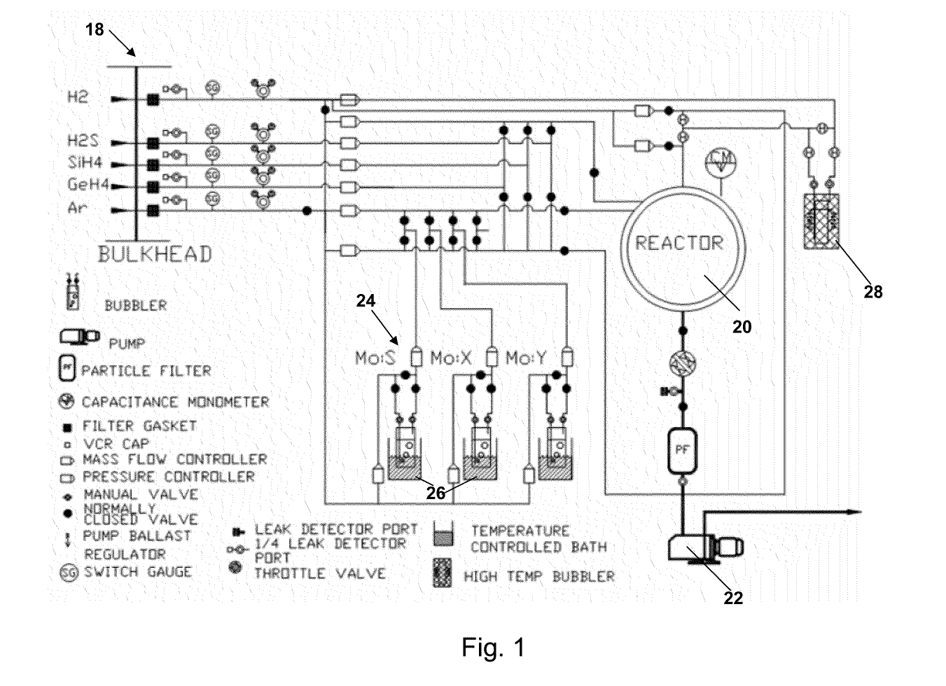

FIG. 1 depicts a schematic of the CVD deposition equipment that was used in this work. Gases are fed from bottles coupled to a gas panel 18 into a vacuum reactor chamber 20 through a showerhead located inside chamber 20 which contains gas inlets 22 for the precursor vapors and carrier gases supplied form gas panel 18 which in this case is hydrogen (H₂) and or argon (Ar). Gas panel 18 also includes bottles and associated valving mechanisms for the gas precursors of germanium and sulfur, such as germane (GeH₄) and hydrogen sulfide (H₂S). Heating of chamber 20 is achieved through resistive heating of SiC-coated graphite filaments or alternatively by inductively coupled “rf” heating or by lamp heaters. A vacuum pump 22 provides an appropriate vacuum to chamber 20, the chamber pressure is recorded through a capacitance manometer. The temperature of chamber 20 is recorded via thermocouples that are positioned in close proximity to the substrate platter or by pyrometers or other means. Wafers to be deposited upon are mounted on a substrate platter that can be equipped with a rotation assembly rotated by an external motor or even internal gas turbine rotation. Chamber 20 is equipped with hardware for wafer processing through an automated wafer transfer robot and load lock chamber (not shown).

FIG. 1 also depicts three bubbler sources 24, one each for any liquid precursor such as germanium chloride (GeCl₄) or a liquid sulfur precursor such as diethyl sulfur (DES) One for the spares can be used for doping/alloying precursors if so desired. More bubblers can always be mounted on a given system. Suitable doping/alloying elements include group IIIA, IVA, VA elements plus some refractory metals, i.e. W, Ta, Mo and Ti; for example. Bubbler sources 24 are each surrounded by liquid baths 26 to maintain the precursors at the desired temperatures. Additional bubbler or other sources can also be added as needed. The precursor vapors are transported to the showerhead by the carrier gas bubbled therethrough, from there they are fed into the chamber. Additionally a source 28 for accommodating a solid precursor such as elemental sulfur is provided. The elemental sulfur when heated gives off vapors which are routed to chamber 20. The elemental sulfur can be placed in reservoirs within the deposition chamber 20 wherein the heating elements used to heat the substrate platter can also be used to heat the elemental sulfur.

In order to deposit the films at temperatures low enough to enable deposition on polymer substrates a plasma rf generator is include in chamber 20. The plasma generator, in this case, operates at 180-250 kHz with a maximum power output of approximately 216 Watts to create a plasma in the system; although we believe that higher or lower frequencies can equally well be used with likely similar results at like or different powers. It should also be noted that rf generators operating in the MHz frequency range or the microwave frequency range (GHz) may also be used. The reactors used in the plasma assisted process for growing GeS may also include: a rotating disc or static reactor with a ring; a rotating disc or a static reactor with a plate; a rotating disc or a rotating disc reactor with a ring and/or a rotating disc reactor with a plate. A reactor having strong central laminar flow is also useable herein wherein smaller flows are introduced at different sections along the wall such that they do not significantly mix going into the reactor and produce compositionally graded films at the growth plane in a non rotating disc reactor.

Furthermore, the Process may include the use of the plasma to first clean the deposition surface. The plasma can be used alone with process gas or with a known etchant such as Chlorine and two or more plasma generating electrodes may also be used. The plasma may be used to assist with the deposition of one or more of the precursors. Also silver (Ag) deposition equipment may also be part of the equipment to permit the formation of GeS—Ag semiconductor devices. In the later case the deposition of the silver in a co-transfer cluster chamber system may also be used with the great advantage of not exposing the GeS film to the environment before the Ag is deposited. Alternatively, the plasma can be used in conjunction with a hydrocarbon gas to generate a removable carbon based protective/sealing or contact layer to the deposited film

### MOCVD Processes

In this section we describe our evolutionary process to achieve a viable production process that succeeded in delivering device quality films (of which working devices were made). As we proceeded, we modified the composition and chemistry as necessary to obtain deposition parameters that provide good compositional control; process parameters evaluated included process pressure, temperature, vapor concentration, chemistry, pre- and post-treatments, and so on. We spent significant time in evaluating reaction pathways and solving chemical processing issues. Table A located at the end of this specification lists examples of the various deposition parameters and precursors used in this work. In order to determine the composition of the deposited films we recorded XRF, XRD, and SMIS scans of different samples.

Initial efforts to deposit GeS with the metalorganic Diethyl-Sulfide (DES) did not produce desirable films. A wide range of Ge deposition rates were achieved with and without DES, with and without plasma; it is apparent that the DES chemistry is not presently working sufficiently for commercial applications. Another concern with DES, or other metalorganic sulfur sources, is carbon contamination. Apparently the presence of DES in the chamber does not retard the deposition of Ge. We believe this is because of the temperatures required to decompose the precursors are also sufficient to evaporate the S except at very high S to Ge ratios; ratios too high to be economically feasible for CVD when using a metalorganic precursor. Additionally, initial effort deposition temperatures were from 100-675° C.; deposition times were 5-30 minutes; GeH₄ flows of 1.5-7.5 sccm. It appears the H₂ may assist in S removal by way of H₂S formation over a wide temperature range. We also evaluated using GeCl₄ in this period. The attempt to deposit using a GeCl₄ and DES chemistry failed to produced any measurable Ge or sulfur film; however a more extensive process parameter study could realize a working result. Process parameters were again varied in this portion of the film growth investigation. In fact, etch pits in the silicon substrate suggests that silicon reduction of GeCl₄ is thermodynamically more favorable than hydrogen reduction.

Our review of the etch pits in the silicon found in electron microscope photographs suggests that silicon reduction of GeCl₄ is thermodynamically more favorable than hydrogen reduction. We propose that reaction (1) is preferred over reaction (2):

GeCl₄+Si→Ge+SiCl₄ (1)

GeCl₄+2H₂→Ge+4HCl (2)

Since we were not able to easily produce high sulfur concentration films using DES as a precursor then logically we need to explore a different source. A most likely source would be H₂S as the chemistry:

GeH₄+2H₂S←→GeS₂+4HCl (3)

which is reported to be thermodynamically favored at high temperatures. Atmospheric CVD of GeS₂ using this chemistry has been reported to occur between 450-600° C. [C. C. Huang, D. W. Hewak, J. V. Badding, “Deposition and Characterization of Germanium Sulphide Glass Planar Waveguides,” Optics Express (The International Electronic Journal of Optics), Vol 12, No. 11, May 31, 2004, pp 2501-2506]

In order to increase the S concentration while keeping future manufacturing costs low led us to pursue using H₂S as the source of sulfur. We had not started with this S source because as a gas it requires greater safety considerations. Initial low S to Ge ratios (<˜5) also showed no S in film depositions. We next increased the ratio to ˜25 and achieved S in the film as seen in XRF data. Based on the results achieved with the 25:1 S:Ge precursor ratio, showing for the first time detectable levels of S in the films, the next set of experiments focused on higher ratios and revisiting the other chemistries using Ar as the carrier gas (to eliminate suspected H removal of S by evaporation and/or the formation of protonated thiogermanic acid H₄Ge₄S₁₀, which would also counter film growth). The first objective was achieved by increasing the H₂S flow and or decreasing GeH₄ flow. The range of S:Ge investigated was 3:1 to 250:1 using XRF compositional feedback. Samples of these films were characterized and found to achieve a maximum S concentration of ˜10 to 15%. While this S concentration is low, films were sent for device processing. The result was the conclusion that more S is needed in the films, which should be achievable by further increasing the H₂S concentration; however, this is not a promising economical path.

At a constant deposition temperature of 200° C., the overall deposition rate decreases with increasing S:Ge ratio, which is to be expected at a fixed Ge source flow. The decrease in deposition rate occurs even as the silicon substrate is replaced with quartz which has been observed to yield higher Ge growth rates than silicon in this deposition system. While this substrate effect is not fully understood, it may be the result of differences in mass and thermal contact with the susceptor or differences in coupling between the substrate and the radiant heating source.

Although some of the hydrogen was removed from the process the total amount in the process remains high because the precursors have 90 and 95% H₂ from the germane and H₂S respectively (ie we were using the Germane and hydrogen sulfide diluted in hydrogen). Therefore, in order to achieve the desired ratios our only option was to actually increase the total flow of H₂ in the process. One of the effects of adding Ar to the process appears to be an increase in the operating pressure at which we are able to sustain the plasma. Future work could of course use pure germane and hydrogen sulfide or the same diluted with Ar in a system with Ar as the only carrier gas. We infer that other inert gases could also be used.

Regarding the relationship between deposition temperature and the deposition rate on silicon substrates at a constant S:Ge precursor ratio of 25:1. There is an apparent maximum in the deposition rate at 200° C., however, the S:Ge ratio in the film is constant over a large temperature range for a constant precursor ratio of 25:1. Above 250° C. the films are more Ge rich but overall the level of S is below the desired level needed. The highest level of S (12%) measured was deposited at a S:Ge (H₂S:GeH₄) precursor ratio of 50:1 and deposited (plasma assisted) at 200° C. with Ar carrier gas on a quartz substrate.

Revisiting previous chemistries: DES+GeCl₄ and H₂S+GeCl₄ and replacing H₂ with Ar as the carrier gas produced mixed results. We were unable to produce Ge or sulfur in deposited films using DES and GeCl₄. However, using the H₂S—GeCl₄ chemistry yielded somewhat promising results. We were able to establish that Ge and sulfur could be formed from these precursors in a thermal only deposition process. Relevant process conditions were a surprising low substrate temperature of 200° C., S:Ge precursor ratio of ˜3:1, precursor flow rates of 20:7 sccm, substrate temperature of 200° C. and total reactor pressure of 35 Torr with Ar carrier gas. In the XRF spectrum we found that sulfur K_{α1} and K_{β1} peaks at 2.31 & 2.46 KeV are obscured by an unknown peak from the substrate the germanium K_{α1} peak is clearly visible at 9.89 KeV indicating its presence in the film. The most reasonable explanation for the presence of Ge is by the following reactions:

2H₂S+GeCl₄→4HCl+GeS₂ (1)

or a reaction with the substrate:

Si+GeCl₄→SiCl₄+Ge (2)

not only is the second reaction thermodynamically unfavorable but depositions where the substrate is coated with Pt, which should cut off the reaction pathway, yield this result. We are then left with the conclusion that the first reaction is most likely to have produced the Ge shown in the spectra.

The significance of this accomplishment is that a thermal process produces a more stable Ge—S material that is not susceptible to evaporation, a challenge with the plasma assisted process for this chemistry set. When using H₂S 5% in H₂ we have not been able to try the H₂S in Ar to eliminate the H₂ from the H₂S—GeH₄ process. Since the GeS₂ glass transition temperature is reported to be 456° C. and crystallization temperature of 620° C., producing a stable amorphous film is well within the range of the process. Furthermore, the material deposited using H₂S and GeCl₄ has the appearance of polycrystalline grain.

Upon evaluating the matrix of precursors used—GeH₄, GeCl₄, DES, H₂S, and other potential MOGe and MOS precursors; we concluded that GeH₄ and H₂S would be the best to focus on. We next analyzed the situation and determined what is needed to increase the S concentration in GeH₄—H₂S produced films. Specifically, we used GeH₄ and H₂S diluted to 5% concentrations in H₂— this was deemed not optimum because the H₂ effectively reduces the S, helping it to evaporate from the surface and or make acid, as reference above. Therefore, we believe we should use either 100% concentrations or use Ar as the dilution gas. We had used diluted toxic gases because of safety concerns. However, based upon the understanding that pure undiluted source gases or at least only diluted with an inert gas such as Ar would work; we also looked to an even less costly approach to achieve the same desired effect. These considerations and the desire to achieve working devices—at very low cost—led us to elect to modify the system yet again in order to use elemental S in the process to mitigate H₂ effects and to increase the S concentration in the gas phase and in the deposited films. The decision to use elemental S was an important breakthrough because, as is discussed below, it allowed us to achieve usable device material and to do so with a highly economical manufacturing process at very low temperatures.

### GeH₄ and Elemental S Vapor

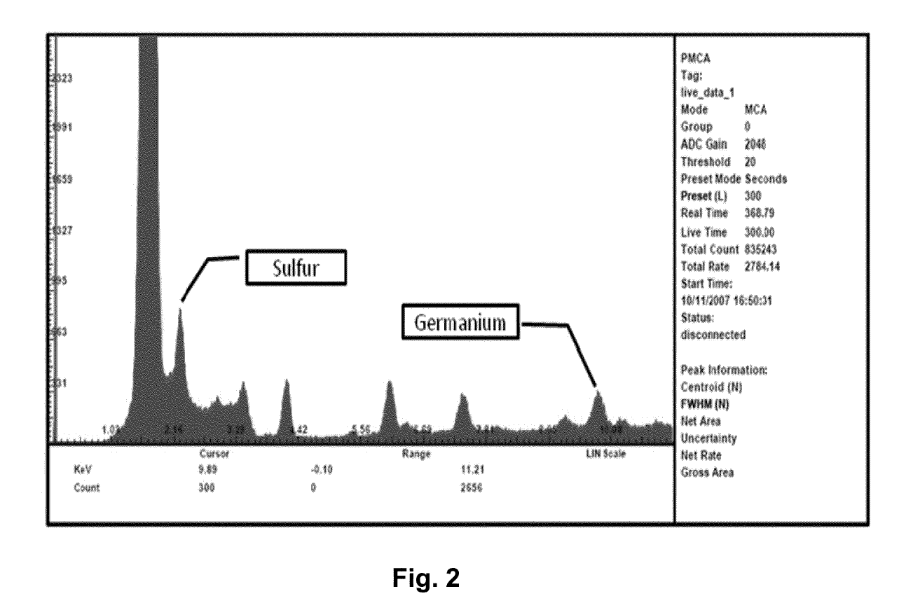

While we had finally achieved measurable S in the films and device functioning films using H₂S and GeH₄, the in film ratio was estimated to be low —S:Ge˜1:10 to 2:10 when the desired amounts are in the range 60:40. Further, these results are still rather low to make devices. While we believe we can use H₂S and GeH₄ in either 100% concentrations or diluted in Ar to achieve the desired S concentrations (eliminating the effects of H enhanced S removal) we decided to evaluate elemental S as a CVD precursor. As a quick test, we modified the source to incorporate a sulfur reservoir in the reactor and used source holder temperature to control the vapor pressure. Through this approach we were able to achieve high or low S to Ge ratios. However, at a temperature of 120° C. using plasma process enhancement we achieved S:Ge compositions as high as 2:1 more than the targeted 60:40 ratio. Somewhat surprisingly, this was accomplished at a very low S:Ge gas phase concentration ratio (˜0.1:1)—in contrast to the high ratio (˜250:1) when using H₂S. We found that by setting the S temperature that we could thereafter control the composition by varying the GeH₄ flow—this method proved to be precise. Using S instead of H₂S greatly lowers cost, odor and safety concerns. The result was a significant success as shown in the XRF data of FIG. 2; where, we have demonstrated more S in the film than Ge. As a result, we have developed a new, scalable and economical approach to producing GeS:Ag devices. This approach may also be likened to Gas Source Molecular Beam Epitaxy (GSMBE) or Chemical Beam Epitaxy (CBE) approaches. The deposition procedures described herein are extended to include the slightly modified approaches of GSMBE and CBE.

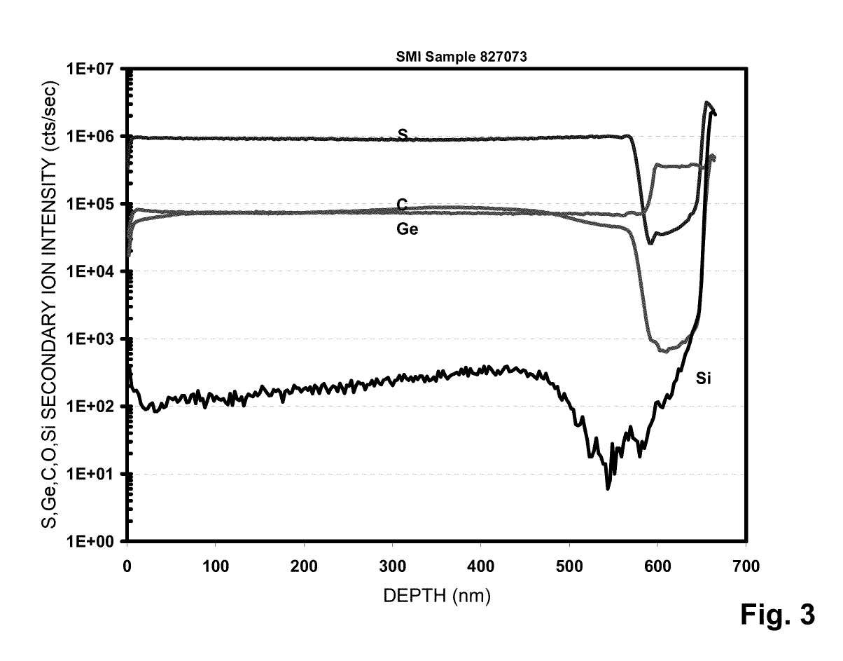

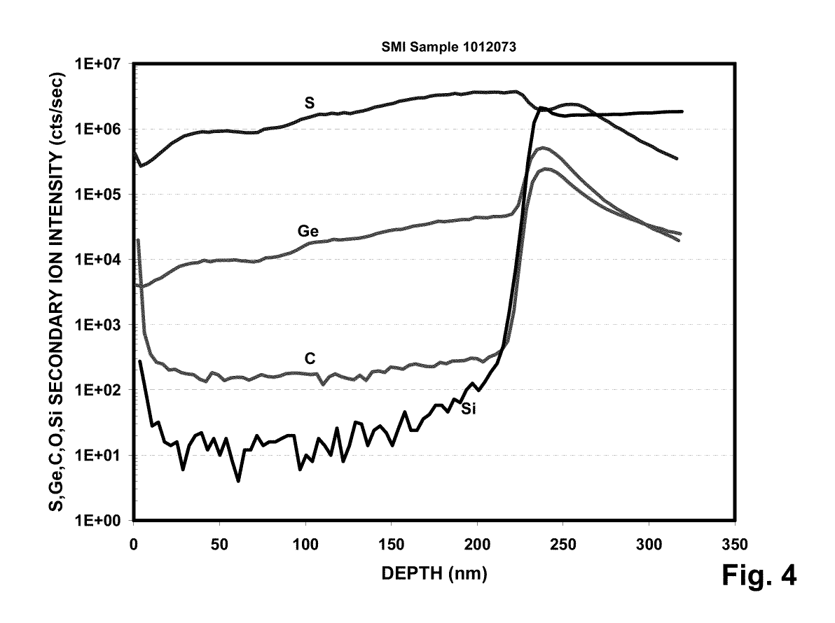

FIGS. 3 and 4 compare GeS films grown with GeH₄ and H₂S (FIG. 3) and S (FIG. 4). Several features are discernable. While the absolute values of composition are uncalibrated, it can be seen that the Ge concentration is much higher in the H₂S sourced system and the concentration appears more steady through the film. However, the C concentration is also significantly higher. The O concentration, while not shown, is also slightly higher. This is likely due to post deposition oxygen diffusion; however, the C concentration we believe to be highly deposition technique dependent. (It is possible the C is from the graphite substrate holder; however, we would have expected the effect to be much less different between the samples). The S and GeH₄ depth profile appears to be less stable; however, this may or may not be the case and may be an artifact of sputter rate stabilization in a high S concentration film or the fact that the evaporation rate in this quick approach to prove our concept is less stable than can be achieved in a refined designed system. We believe this depth profile data shows a critical importance in the sources applied to making films and in particular; our invented elemental —GeH₄ hydride deposition approach (with or without plasma). If the C is from the graphite substrate holder there are several obvious solutions including the use of SiC or SiC coatings on the graphite, use of Si or sapphire wafer carriers, and so on. The convenience, for proof of concept, of using the sulfur source within the heated deposition zone can be much better controlled by separating and independently controlling the source of sulfur—an example of which is shown in the system schematic diagram where the sulfur source can be operated either in a sublimation role or, with the sulfur melted—, the sulfur source can be operated as a conventional bubbler.

We also grew GeS films at a low temperature (100-120° C.) on a polymer surface using S and GeH₄. This is significant because with the low temperature photodiffusion process (for Ag), it opens the door to very radiation hard memories and other devices that benefit from a variable state, being produced on flexible substrates. While this deposition was carried out as a target of opportunity, the impact for future implementations is just beginning to be understood. We have started by performing photodiffusion into the film on the polymer and then evaluating lateral hysteresis in the films on the polymer. Furthermore the present MOCVD methodology may be used to produce GeSAg by using S, GeH4 and metalorganic Ag compounds. such as AgF; [Ag(C4F7)]n; Ag(b-diketonate)PR3; Silver vinyltrimethylsilane; Silver tetramethylethylenediamine; Ag(O2CCF3)(PEt3); Ag(O2CC2F5)(PEt3); Ag(O2CCH2SiMe3)(PMe3) and Ag(O2CCH2SiMe3)(PEt3). Very promising Ag precursors are Silver carboxylates and in particular: silver(1) 2,2-dimethylpropionate ((CH3)3COOAg), also known as silver pivalate, which deposits silver in the range of 225-400 C by conventional MOCVD.

### Fabricate Single Cell Test Devices

Single cell test devices were fabricated to assess the electrical characteristics of the deposited layers. Specifically, after the GeS films were deposited and characterized by XRF, they were sent for both lateral and mesa test cell fabrication. The lateral test cells are for material qualification and the mesa structures are for performance characterization. Care was taken to account for the ranges of composition and thickness of the films. Standard Ag evaporation and photodiffusion techniques were used to inject the Ag metal ions into the GeS and so form the solid electrolyte. The test structure added the top electrode stack by physical vapor deposition, optical lithography, and plasma etching. The finished devices have geometries (active area diameter) ranged from 10 μm to 100 nm.

Using the substrates with the Ge—S base glass layers, two device types were fabricated. The first devices were “lateral” structures with coplanar tungsten and silver electrodes. The large electrode spacing (several tens of μm) and surface electrodeposition in lateral structures allow us to establish the basic functionality of the films, i.e., we can determine if Ag can be dissolved into the base glass to create an electrolyte and if the resulting solid electrolyte support electrodeposition of a conducting pathway. If surface electrodeposits are observed, the structures undergo electrical characterization to verify switching. Once film functionality was confirmed, vertical devices were fabricated. These structures consist of an electrode-electrolyte-electrode stack and are closer in form to actual memory devices.

The lateral devices were fabricated on a sample which had relatively high resistivity silicon supporting the base glass to reduce the parasitic (non-Faradaic) current between the electrodes. A 35 nm thick optically transparent layer of Ag was deposited by thermal evaporation on the Ge—S and then exposed to 8.3 mW/cm² UV light (436 nm) from a Hg vapor lamp for 30 minutes to photodissolve the silver. A color change was noted, indicating that the silver had reacted with the Ge—S. An array of Ag (oxidizable) electrodes was then deposited by evaporation through a shadow mask. The counter electrode in this test structure was a moveable tungsten probe, held in a micromanipulator that was placed on the electrolyte within a few tens of μm of a selected Ag electrode. Contact to the Ag electrode was also made via such a probe. Both probes were connected to a Semiconductor Parameter Analyzer (SPA) and the voltage was swept such that the Ag electrode was positive with respect to the W probe on the electrolyte. This resulted in a clearly visible surface electrodeposit that extended from the W tip toward the Ag.

Vertical devices were then fabricated using substrates which had the Ge—S films deposited on highly conductive Pt layers on silicon substrates. In this case the Pt would act as the inert (non-oxidizable) electrode. To form localized electrolyte regions, 35 nm of Ag was deposited by thermal evaporation on the Ge—S through a shadow mask and then photodissolved as before. Ag top electrodes were also formed using the same shadow mask to complete the Pt—AgGeS—Ag stack. These devices were characterized on a probe station using quasi-static measurement with a semiconductor parameter analyzer, as well as pulse train techniques (arbitrary waveform generator and a fast digital storage oscilloscope), and impedance spectroscopy. The device was swept from −ve to +ve to −ye voltage with a current compliance of 1 mA. The write threshold was 1 V and the full erase occurred at −1 V. The off resistance was above 1 GΩ and the on resistance was approximately 1 kΩ—a range of 6 orders of magnitude, which is more than sufficient for device operation. Based upon these results and film refinements, vertical structure mesa devices were made.

A simple vertical device that proves basic functionality was made. These devices were then characterized using the SPA by sweeping the voltage from 0 to 4V to 1.1V and then from 0 to 0.4 V to confirm the resistance-lowering effect, as shown in the resistance-voltage plot below. Switching was clearly evident with a reduction in resistance from 20 MΩ to 750 kΩ at a read voltage of 1.1V. The write threshold voltage in these devices was in the order of 2.5 V, which was higher than ideal and indicates underdoping of the electrolyte film throughout its thickness. These results are not a surprise under evaluation and are in fact very promising—specifically the film thickness is not well known in these test structures so under doping (or overdoping) at this stage should be anticipated. Further, the non-oxidizing Pt substrate is new to the process—it was used because of reasonable availability; but its effect on oxidation and performance are not known. The threshold voltages are a bit high, indicating underdoping, but switching is evident. The write threshold is about 2.5 V and the on-state is non-ohmic but considerably lower than the off-state (R_{off}=20 MOhm and Rₒₙ=750 kOhm at a read voltage of 1.1 V).

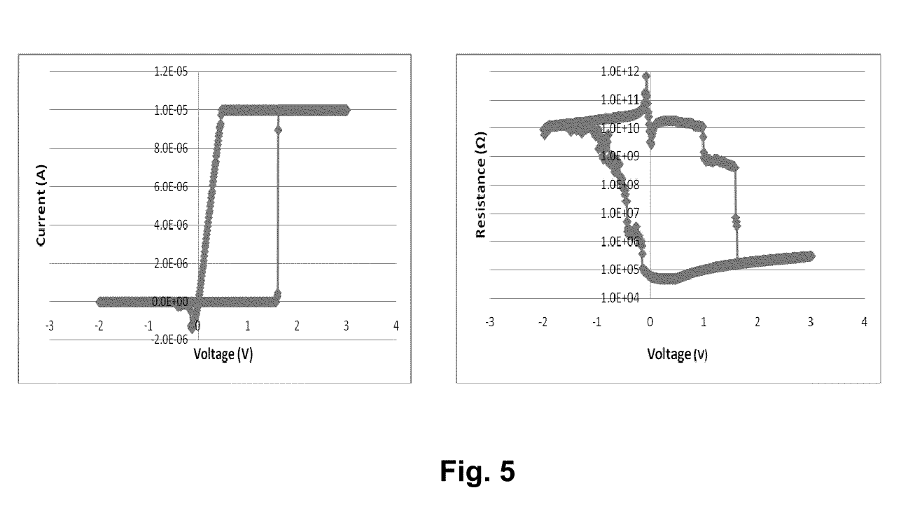

Additionally about 16 nm of Ag was photodissolved into the film on polymer to ensure that all the Ag was dissolved and programmed the devices with a 10 uA write current. Apart from the fact that the write threshold is high, indicating that the silver content is a bit lower than optimal (as expected for the Ag thickness used), the devices behave quite well as seen in FIG. 5. The off resistance was around 10 GOhms and this dropped to about 40 kOhms after switching. We saw some regions on the substrate where the device threshold was around where it should be (˜0.5 V)—probably due to local variations in thickness and composition. In addition to silver, copper is an alternative material which may also be photodissolved to form an electrode.

These results conclusively prove that CVD (and equivalently CBE or GSMBE) processes are capable of producing PMC materials for devices such as CBRAMs and other MEMRISTOR devices. The initial results show great promise and based upon the unoptimized thicknesses and composition, it is to be expected that initial devices are optimizable. Importantly, the photodiffusion process must also be optimized to the film thickness and so the results are doubly impressive when it is recognized that material production, contact formation and electrolytic conversion have all been brought together for the first time by different parties and such good results have been achieved.

We theoretically analyzed the samples for radiation hardness. The programmable metallization cell (PMC) memories discussed in this project utilize electrochemical control of nanoscale quantities of metal in thin films of solid electrolyte. The base cell uses inert electrodes in contact with a Ag+ containing electrolyte film. This creates a device in which information is stored using large non-volatile resistance change caused by the reduction of the metal ions. Overall, because of the amorphous nature and either conducting or low conducting nature of the active layer ionizing radiation is unlikely to be sufficient to motivate electrolytic ion motion to change state; nor is such radiation likely to change the already amorphous state. More likely is that the electrolytic—backbone nature of the structure will cause itself to effectively heal from any residual voltage spike induced drift. Similarly, other forms of destructive radiation would need to exceed very high fluencies before sufficiently damaging the structure; more likely are that other circuit features would fail first.

TABLE A

| | | | Deposition | | | | | |
|---|---|---|---|---|---|---|---|---|
| S | Ge | Precursor | Temperature | Pressure | Deposition | Plasma/ | | |
| Precursor | Precursor | S:Ge | (C.) | Torr | Time | Thermal | H₂/Ar | Substrate |
| DES | GeH₄ | 1.7:1 | 402 | 12.3 | 15 | Plasma | H₂ | Si/quartz |
| DES | GeH₄ | 1.7:1 | 300 | 12.3 | 25 | Plasma | H₂ | Si/quartz |
| DES | S only | ∞ | 300 | 12.3 | 20 | Plasma | H₂ | Si |
| DES | S only | ∞ | 32 | 10 | 30 | Plasma | H₂ | Si/quartz |
| DES | GeH₄ | ∞ | 500 | 10 | 30 | Plasma | H₂ | Si/quartz |
| DES | GeH₄ | 3:1 | 300 | 10 | 30 | Plasma | H₂ | Si/quartz |
| DES | GeH₄ | 3:1 | 200 | 10 | 20 | Plasma | H₂ | Si/quartz |
| DES | GeH₄ | 3:1 | 100 | 10.6 | 20 | Plasma | H₂ | Si/quartz |
| DES | GeH₄ | 3:1 | 350 | 10 | 20 | Plasma | H₂ | Si/quartz |
| DES | GeH₄ | 3:1 | 350 | 10 | 30 | Plasma | H₂ | Si |
| DES | GeH₄ | 3:1 | 600 | 12 | 15 | Thermal | H₂ | Si |
| DES | GeH₄ | 3:1 | 500 | 10 | 20 | Thermal | H₂ | Si |
| DES | GeH₄ | 4:1 | 600 | 10 | 10 | Thermal | H₂ | Si |
| DES | GeH₄ | 1.5:1 | 600 | 10 | 5 | Thermal | H₂ | Si |
| NA | GeCl₄ | 0 | 400 | 10 | 10 | Thermal | H₂ | Si |
| NA | GeCl₄ | 0 | 600 | 18 | 10 | Thermal | H₂ | Si/quartz |
| NA | GeCl₄ | 0 | 300 | 10 | 10 | Thermal | H₂ | Si/quartz |
| NA | GeCl₄ | 0 | 200 | 17 | 10 | Thermal | H₂ | Si/quartz |
| NA | GeCl₄ | 0 | 400 | 10 | 10 | Thermal | H₂ | Si/quartz |
| NA | GeCl₄ | 0 | 500 | 10 | 10 | Thermal | H₂ | Si |
| DES | GeCl₄ | 1:1 | 550 | 13.6 | 15 | Thermal | H₂ | Si/quartz |
| DES | NA | ∞ | 275 | 7.8 | 10 | Plasma | H₂ | Si/quartz |
| DES | GeH₄ | 3.5:1 | 250 | 8 | 10 | Plasma | H₂ | Si/quartz |
| DES | GeH₄ | 3:1 | 675 | 8 | 5 | Thermal | H₂ | Si/quartz |
| DES | GeH₄ | 4:1 | 150 | 8.6 | 10 | Plasma | H₂ | Si/quartz |
| DES | GeH₄ | 4:1 | 100 | 8.7 | 20 | Plasma | H₂ | Si |
| NA | GeCl₄ | 0 | 400 | 12 | 10 | Plasma | H₂ | Si |
| NA | GeCl₄ | 0 | 400 | 13 | 20 | Plasma | H₂ | Si |
| NA | GeCl₄ | 0 | 400 | 12.6 | 10 | Plasma | H₂ | Si/quartz |
| H₂S | GeCl₄ | 1:1 | 450 | 15.1 | 20 | Thermal | H₂ | Si |
| H₂S | GeCl₄ | 1:1 | 600 | 15 | 15 | Thermal | H₂ | Si |
| H₂S | GeCl₄ | 1:1 | 450 | 13.7 | 15 | Plasma | H₂ | Si |
| H₂S | GeH₄ | 4:1 | 400 | 10 | 15 | Plasma | H₂ | Si |
| H₂S | GeH₄ | 4:1 | 400 | 7.5 | 15 | Plasma | — | Si |
| H₂S | GeH₄ | 4:1 | 500 | 7.5 | 15 | Thermal | — | Si |
| H₂S | GeCl₄ | 3:1 | 505 | 24.5 | 25 | Thermal | Ar | Si |
| H₂S | GeCl₄ | 3:1 | 300 | 25 | 10 | Thermal | Ar | quartz |
| DES | GeCl₄ | 10:1 | 620 | 25 | 15 | Thermal | Ar | Si |
| H₂S | GeCl₄ | 2.5:1 | 250 | 10.2 | 25 | Plasma | Ar | Si |
| H₂S | GeH₄ | 5:1 | 205 | 10.2 | 40 | Plasma | Ar | Si |
| H₂S | GeH₄ | 5:1 | 326 | 12 | 40 | Plasma | Ar | Si |
| H₂S | GeH₄ | 5:1 | 325 | 10.2 | 30 | Plasma | Ar | quartz |
| H₂S | GeH₄ | 2.5:1 | 150 | 11.2 | 35 | Plasma | Ar | Si |
| H₂S | GeH₄ | 10:1 | 250 | 14.3 | 30 | Plasma | Ar | Si |
| H₂S | GeH₄ | 25:1 | 100 | 19.6 | 35 | Plasma | Ar | Si |
| H₂S | GeH₄ | 25:1 | 150 | 22.6 | 27 | Plasma | Ar | Si |
| H₂S | GeH₄ | 25:1 | 200 | 20.2 | 27 | Plasma | Ar | Si |
| H₂S | GeH₄ | 25:1 | 250 | 20.3 | 27 | Plasma | Ar | Si |
| H₂S | GeH₄ | 25:1 | 300 | 20.2 | 27 | Plasma | Ar | Si |
| H₂S | GeH₄ | 25:1 | 325 | 19.2 | 25 | Plasma | Ar | Si |
| H₂S | GeH₄ | 50:1 | 200 | 19.8 | 30 | Plasma | Ar | quartz |
| H₂S | GeH₄ | 50:1 | 250 | 19.6 | 30 | Plasma | Ar | quartz |
| H₂S | GeH₄ | 17:1 | 250 | 16.6 | 15 | Plasma | Ar | Si |
| DES | GeH₄ | 5:1 | 250 | 17.5 | 12 | Plasma | Ar | quartz |
| H₂S | GeH₄ | 25:1 | 220 | 16 | 30 | Plasma | — | Pt/Si |
| H₂S | GeH₄ | 100:1 | 200 | 18.2 | 40 | Plasma | Ar | Si/quartz |
| H₂S | GeH₄ | 250:1 | 200 | 18.2 | 40 | Plasma | Ar | Si/quartz |
| H₂S | GeH₄ | 100:1 | 205 | 16.5 | 22 | Plasma | Ar | quartz |
| H₂S | GeH₄ | 25:1 | 300 | 12 | 15 | Plasma | Ar | Si |
| H₂S | GeH₄ | 20:1 | 250 | 11.2 | 15 | Plasma | Ar | Si |
| H₂S | GeH₄ | 20:1 | 225 | 13 | 15 | Plasma | Ar | Si |
| H₂S | GeCl₄ | 3:1 | 200 | 35 | 15 | Thermal | Ar | Pt/Si |
| H₂S | GeCl₄ | 2:1 | 200 | 30 | 15 | Thermal | Ar | Si, Pt/Si, Qz |
| H₂S | GeCl₄ | 3:1 | 200 | 35 | 10 | Thermal | Ar | Si, Pt/Si, Qz |
| H₂S | GeH₄ | 25:1 | 250 | 19.4 | 25 | Plasma | Ar | Pt/Si |
| H₂S | GeH₄ | 25:1 | 250 | 19.4 | 10 | Plasma | Ar | Pt/Si |
| H₂S | GeH₄ | 50:1 | 200 | 20 | 10 | Plasma | Ar | Pt/Si |
| H₂S | GeH₄ | 25:1 | 575 | 16.8 | 15 | Thermal | — | Si/quartz |
| Sulfur | GeH₄ | na | 200 | na | 1 | Plasma | | Si |
| Sulfur | GeH₄ | na | 150 | 16.4 | 1 | Plasma | Ar | Pt/Si |
| Sulfur | GeH₄ | na | 150 | 16.2 | 5 | Plasma | Ar | Si |
| Sulfur | GeH₄ | na | 135 | 16.0 | 5 | Plasma | Ar | Si |
| Sulfur | GeH₄ | na | 119 | 13.0 | 4 | Plasma | Ar | Pt/Si |
| Sulfur | GeH₄ | na | 122 | 13.0 | 4 | Plasma | Ar | Si |
| Sulfur | GeH₄ | na | 121 | 13.0 | 5 | Plasma | Ar | Pt/Si |
| Sulfur | GeH₄ | na | 120 | 13.0 | 7 | Plasma | Ar | Pt/Si |
| Sulfur | GeH₄ | na | 120 | 14.0 | 7 | Plasma | Ar | Pt/Si |
| Sulfur | GeH₄ | na | 120 | 16.0 | 3 | Plasma | Ar | Pt/Si |
| Sulfur | GeH₄ | na | 120 | 16.0 | 3 | Plasma | Ar | Pt/Si |
| Sulfur | GeH₄ | na | 120 | 16.0 | 3 | Plasma | Ar | Pt/Si |
| Sulfur | GeH₄ | na | 120 | 16.0 | 3 | Plasma | Ar | Pt/Si |
| Sulfur | GeH₄ | na | 120 | 16.0 | 3 | Plasma | Ar | Pt/Si |
| Sulfur | GeH₄ | na | 100 | 13.6 | 8 | Plasma | Ar | Si |
| Sulfur | GeH₄ | na | 120 | 14.6 | 5 | Plasma | Ar | Si |
| Sulfur | GeH₄ | na | 119 | 30 | 4 | Plasma | Ar | Prepared |
| Sulfur | GeH₄ | na | 119 | 9 | 3 | Plasma | Ar | Prepared |
| Sulfur | GeH₄ | na | 118 | 8 | 1 | Plasma | Ar | Prepared |
| Sulfur | GeH₄ | na | 118 | 16 | 0.75 | Plasma | Ar | Prepared |
| Sulfur | GeH₄ | na | 118 | 6.4 | 0.5 | Plasma | Ar | Prepared |
| Sulfur | GeH₄ | na | 119 | 8 | 1 | Plasma | Ar | Prepared |
| Sulfur | GeH₄ | na | 119 | 7.4 | 0.75 | Plasma | Ar | Prepared |
| Sulfur | GeH₄ | na | 119 | 13 | 1.5 | Plasma | Ar | Prepared |
| Sulfur | GeH₄ | na | 118 | 13 | 2 | Plasma | Ar | Prepared |
| Sulfur | GeH₄ | na | 120 | 9 | 1 | Plasma | Ar | Prepared |
| Sulfur | GeH₄ | na | 119 | 13 | 1.25 | Plasma | Ar | Prepared |

### Other Compounds

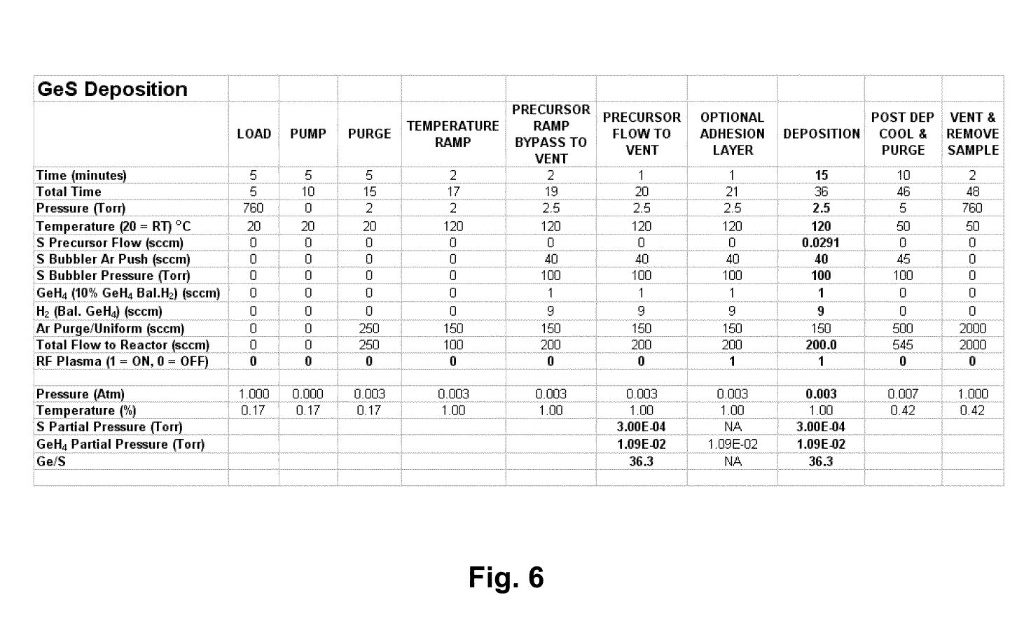

FIG. 6 is a spreadsheet showing a further exemplary process for the deposition of Germanium Sulfide (GeS) in addition to those described above. In the spreadsheet the steps of the process are listed at the top with time progressing from left to right, the parameters and chemicals used in the process are listed in the left hand column. The steps include the loading of the substrate in the CVD chamber labeled as “Load” on the spreadsheet, followed by the pumping of the chamber to a vacuum “Pump”. Thereafter the chamber is purged “purge” with an inert gas, in this case Argon, and the temperature of the chamber is raised “Temperature Ramp” from room temperature to 120° C. Then the carrier gas, in this case Argon, is ramped up “Precursor Ramp Bypass to Vent” to flow to the sulfur precursor which in this case is heated elemental sulfur in a bubbler, however the ramping up of the precursor flow is bypassed to vent away from the chamber. At this same step “Precursor Ramp Bypass to Vent” the carrier gas Hydrogen (H) for the Ge precursor, Germane gas (GeH₄), also begins its ramp up but is also bypassed to vent away from the chamber. At the next step “Precursor Flow to Vent” the precursors after ramping up are bypassed to the vent for a short time. At this time an optional adhesion layer “Optional Adhesion Layer”, which may be pure Ge or another element (or compound or series of layers) is deposited on the heated substrate. Thereafter deposition occurs “Deposition” of the Ge and S on the heated substrate for the appropriate time for the required film, herein 15 minutes. As shown in the spreadsheet the deposition of the adhesion layer and the GeS layer may be aided by a plasma formed at the substrate. After deposition the CVD chamber is cooled down and purged of reactant gases, “Post Dep Cool & Purge”, the chamber is then vented and the sample removed.

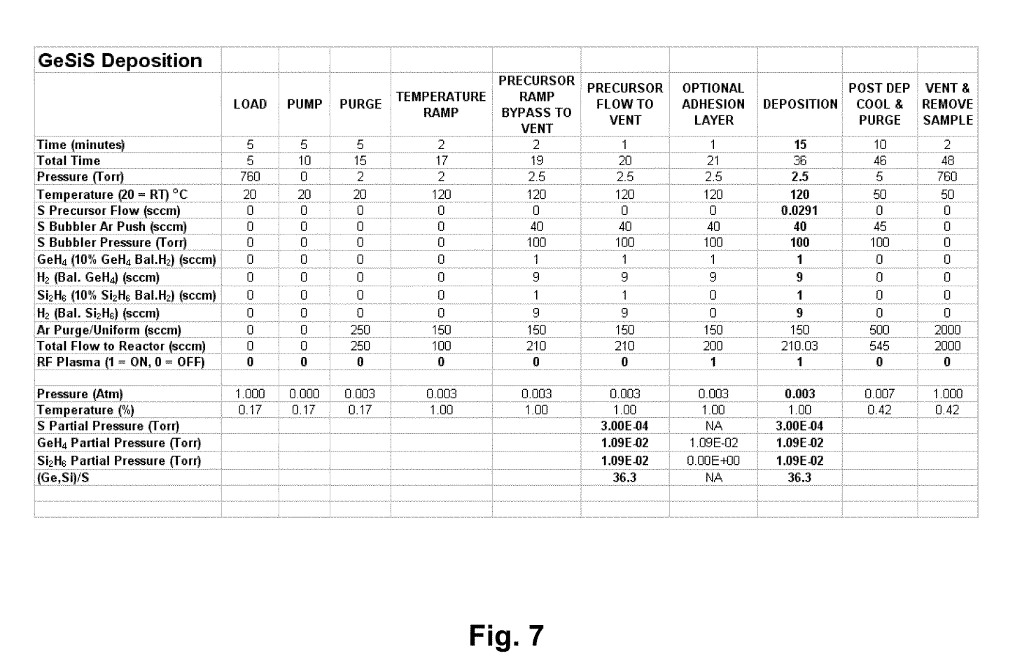

FIG. 7 is a spreadsheet showing the process for the deposition of the ternary compound Germanium Silicon Sulfide (GeSiS). As above in the spreadsheet the steps of the process are listed at the top with time progressing from left to right, the parameters and chemicals used in the process are listed in the left hand column. As can be seen the steps are similar to the deposition of GeS shown in FIG. 6 with elemental sulfur used as the precursor for sulfur and Germane gas (GeH₄) used as the precursor for germanium. However, an additional precursor Disilane gas (Si₂H₆) is used simultaneously with S and Ge to deposit silicon to form GeSiS, silane (SiH₄) is also a suitable precursor for silicon in this process.

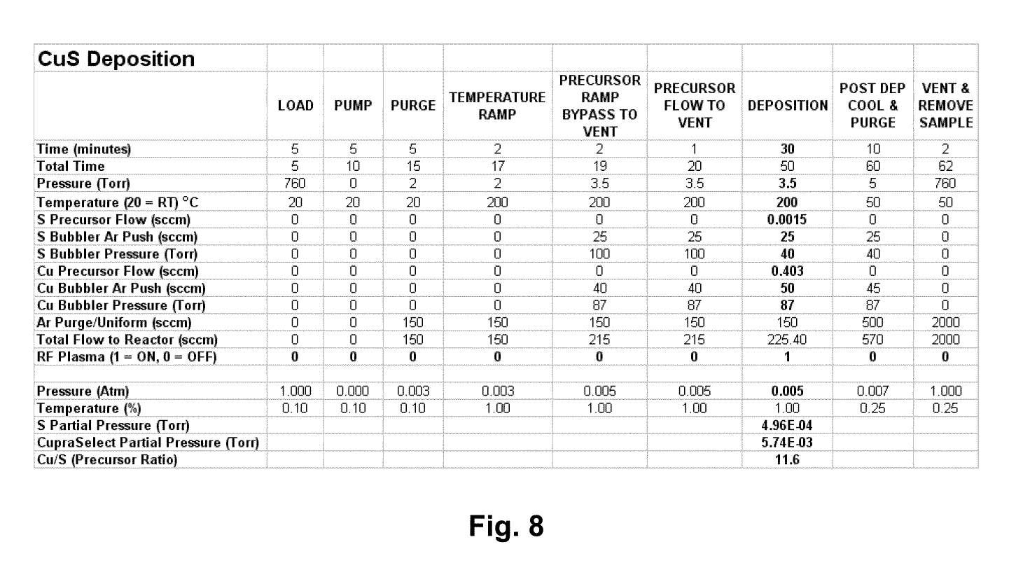

FIG. 8 is a spreadsheet showing the process for the deposition of the compound Copper Sulfide (CuS). As above in the spreadsheet the steps of the process are listed at the top with time progressing from left to right, the parameters and chemicals used in the process are listed in the left hand column. As can be seen the steps are similar to the deposition of GeS shown in FIG. 6 with elemental sulfur used as the precursor for sulfur and copper trimethylvinylsilane (brand name CupraSelect™) was used as the precursor for copper. The deposition parameters: carrier and purging gases, time, temperature, pressure, flow rates and plasma assist are shown in the spreadsheet.

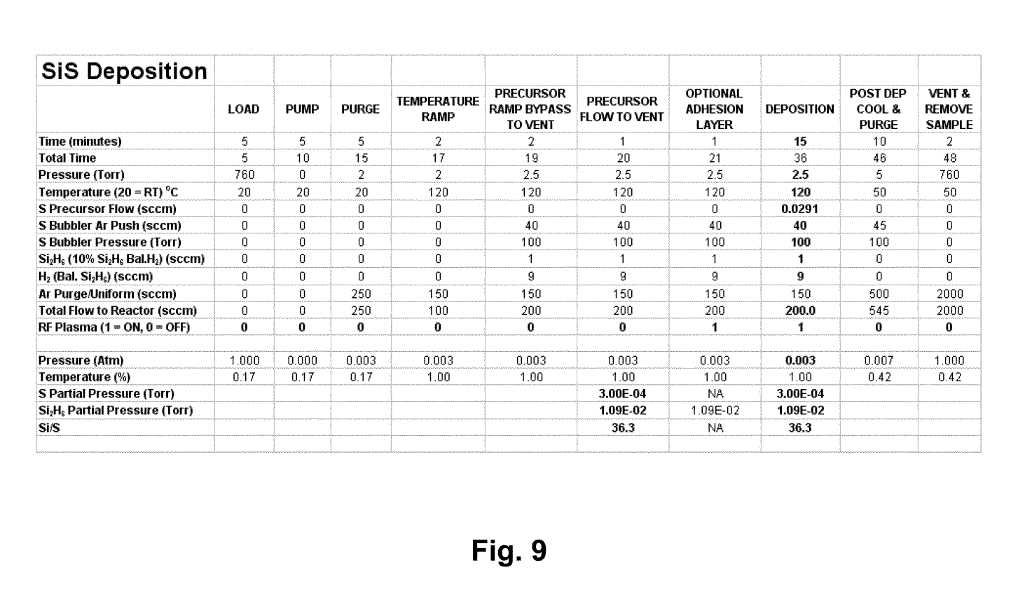

FIG. 9 is a spreadsheet showing the process for the deposition of the compound

Silicon Sulfide (SiS). As above in the spreadsheet the steps of the process are listed at the top with time progressing from left to right, the parameters and chemicals used in the process are listed in the left hand column. As can be seen the steps are similar to the deposition of GeS shown in FIG. 6 with elemental sulfur used as the precursor for sulfur and disilane gas (Si₂H₆) is used simultaneously with S to deposit silicon to form SiS, silane (SiH₄) is also a suitable precursor for silicon in this process. The deposition parameters: carrier and purging gases, time, temperature, pressure, flow rates and plasma assist are shown in the spreadsheet.

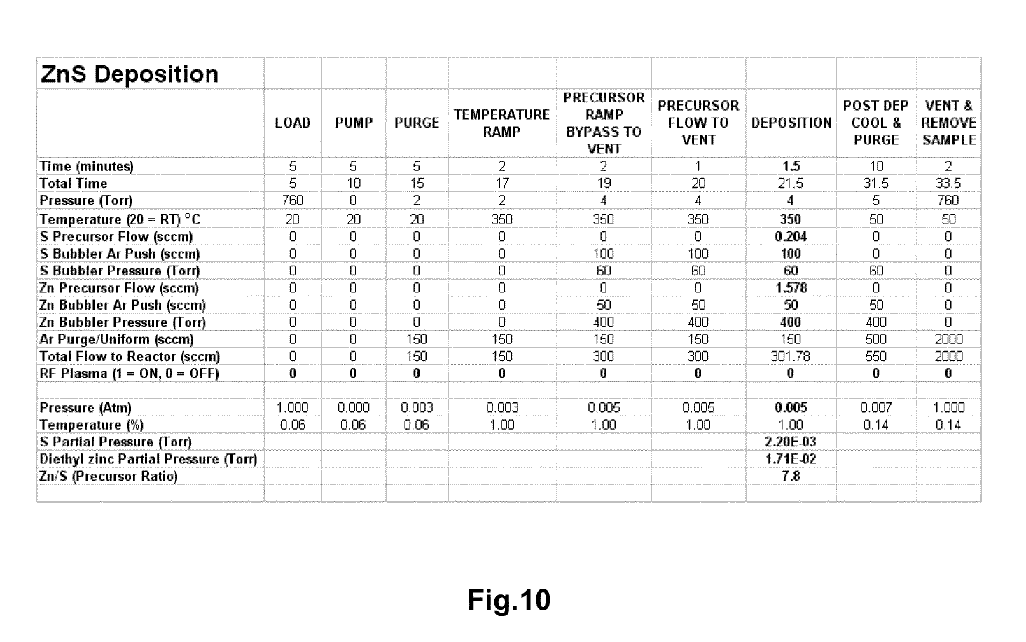

FIG. 10 is a spreadsheet showing the process for the deposition of the compound Zinc Sulfide (ZnS). As above in the spreadsheet the steps of the process are listed at the top with time progressing from left to right, the parameters and chemicals used in the process are listed in the left hand column. As can be seen the steps are similar to the deposition of GeS shown in FIG. 6 with elemental sulfur used as the precursor for sulfur and diethylzinc (C₂H₅)₂Zn, or DEZ, which is used simultaneously with S to deposit silicon to form ZnS, dimethylzinc Zn(CH₃)₂ is also a suitable precursor for silicon in this process. The deposition parameters: carrier and purging gases, time, temperature, pressure, flow rates and plasma assist are shown in the spreadsheet.

In addition to the compounds described above, FeS films can be deposited by the procedures with the use of suitable Fe precursors, such as but not limited to, Ferrocene (C₅H₅)₂Fe. Similarly, GeSAg alone or in combination with other compounds may be deposited by the described process using the Ag precursors described above. Additionally, a passivation film, carbon based or other type, may be deposited immediately after CVD growth of a Chalcogenide or other film in the same reactor by utilizing the plasma to deposit a carbon based film. It is also seen that the present process and procedures are capable of using elemental, gaseous and liquid precursors to deposit a wide variety of compounds.

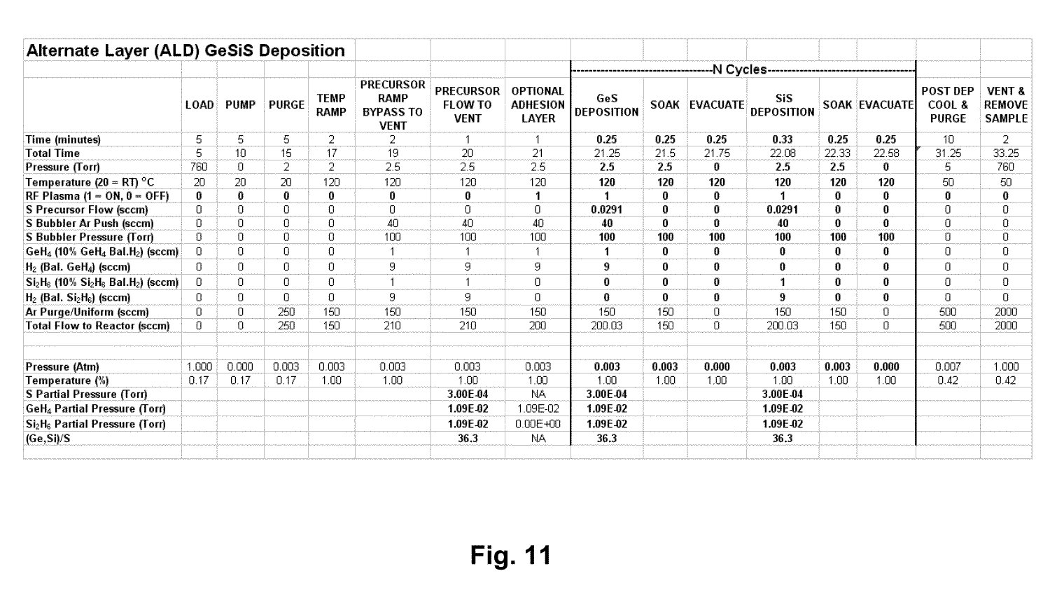

FIG. 11 is a spreadsheet showing the procedure for the deposition of Germanium Silicon Sulfide (GeSiS) with alternating layers of GeS and SiS. Again the steps of the process are listed at the top with time progressing from left to right, the parameters and chemicals used in the process are listed in the left hand column. As can be seen the steps are similar to the other depositions from step “load” to step “Optional adhesion layer” with elemental sulfur used as the precursor for sulfur. After the “Optional adhesion layer” step there follows a series of N repeated steps to form N alternating layers of GeS and SiS. A GeS layer deposition is followed by a short “soak” with the precursor flows turned off, thereafter the CVD chamber is evacuated. Thereafter a SiS layer deposition is followed by a short “soak” with the precursor flows turned off, thereafter the CVD chamber is evacuated to be followed by the GeS and SiS depositions again until the required numbers of alternating layers are formed. Finally the chamber is cooled, purged, vented and unloaded. The precursor pulsing deposition mode may be highly advantageous where surface migration and ultra uniform coatings are desired for coating vias or other challenging geometric structures.

In addition the alternating layer deposition process described in FIG. 11 may also be utilized with plasma assistance. Furthermore, the precursor source or the plasma or both may be turned on and off, i.e. “pulsed” during deposition. The plasma and precursor pulsing CVD is different than the alternating layer deposition approach as it allows some layers to be deposited with an activator, such as the plasma, and then other layers to be deposited without the plasma but then to be treated (exposed) to a plasma before another layer is applied—this approach adds great versatility to the way in which deposited films can be built up.

We have discerned several significant results:
H₂S and GeH₄ can produce GeS films of sufficient quality to make working devices
Elemental sulfur works exceptionally well with GeH₄ and plasma
Elemental sulfur combined with GeH₄ and our plasma approach works at temperatures at least as low as 100 C—perhaps lower yet
The elemental S and GeH₄ approach makes device working films at low and high temperatures
Elemental sulfur works well with silane based compounds, copper based compounds, zinc based compounds, and so on and is relatively safe to handle
This approach should work equally well in Chemical Beam Epitaxy (CBE) or Gas Source Molecular Beam Epitaxy (GSMBE) modes as well
The elemental S and GeH₄ is an exceptionally clean, economical and low abatement process
Since elemental sulfur melts at 120 C, we can easily implement this process in a very clean format wherein we can scale the process; using S vapors like a conventional CVD source using conventional high temperature valves and so forth to control film deposition. —this includes operating the S source as a conventionally bubbler
Importantly, we can introduce a silver (solid or coating) plasma launching electrode within the process chamber because we use silver in the resulting film electrode without fear of contaminating the deposited material (we could also do the same for a Cu doped film).
We have shown composition fine tuning by varying the percent GeH₄ in an S overpressure
The stated ranges are by way of example only and can be varied by those of ordinary skill in the art
The GeSAg complex can be grown using the Ag precursor compounds listed earlier in the document; although we believe the present two step process is likely to be cleaner and more economical

The present invention has been described with respect to exemplary embodiments. However, as those skilled in the art will recognize, modifications and variations in the specific details which have been described and illustrated may be resorted to without departing from the spirit and scope of the invention as defined in the claims to follow.

What is claimed is:

1. A method of depositing a A_{X}S_{Y} where A is at least one of Ge, Si, Cu, Zn, and Fe, S is sulfur and X=0 to 1, Y=0 to 1 on a substrate comprising the steps of:
a) placing the substrate in a reactor chamber;
b) providing a precursor of A;
c) providing a precursor of S;
d) transporting the precursors of Ge, and S to the reactor chamber;
e) heating the substrate so as to cause the precursors of A and S to deposit A and S on the surface of the substrate; and
f) modulating the flow of the precursors of A and S so as to form the desired AₓS_{y} film.

2. The method of claim 1 wherein the precursor of S comprises elemental sulfur.

3. The method of claim 1 further including the step of rotating the substrate during deposition.

4. The method of claim 1 wherein the precursors of A, and S comprise a gas.

5. The method of claim 1 wherein the precursors of at least one of S and A comprise liquid precursors of S and Ge through which a carrier gas is bubbled so as to capture the vapors from the liquid precursors.

6. The method of claim 5 wherein the carrier gas comprises at least one of hydrogen and argon.

7. The method of claim 1 further including the step of providing a plasma to assist the deposition of at least one of the precursors of A and S.

8. The method of claim 1 further including the step of providing a plasma to etch at least a portion of the substrate.

9. The method of claim 1 wherein the precursors of A and S deposit Ge and S simultaneously on the surface of the substrate.

10. The method of claim 1 wherein the precursors of A and S are operated in an alternating manner, with an optional inert purge between layers so as to deposit GeS in a manor known as alternating layer deposition.

11. The method of claim 1 wherein the precursors are operated in an functionally varying manner so as to deposit A and S in layers of varying or oscillating composition on the surface of the substrate.

12. The method of claim 1 further including the steps of providing a precursor of a doping/alloying element or elements, transporting the precursor of the doping/alloying element(s) to the reactor chamber, and depositing the doping/alloying element along with the other constituents of the film.

13. The method of claim 12 wherein the doping/alloying element is selected from the group consisting of: group IIIA, IVA, and VA elements and refractory metals, such as. Selected from the group of W, Ta, Mo and Ti.

14. The method of claim 1 wherein the precursor of S comprises elemental sulfur and the deposition takes place at 100 C to ˜500 C, preferentially at 100 to 200 C

15. The method of claim 1 wherein the precursor of S comprises elemental sulfur supplied from a reservoir within the reactor chamber.

16. The method of claim 1 wherein the precursor of S comprises elemental sulfur supplied from a reservoir remote from the reactor chamber where the sulfur is melted and a carrier gas is bubbled through it under controlled conditions to deliver S vapor with the carrier gas to the reactor chamber.

17. The method of claim 1 wherein the substrate comprises a polymer, metal foil, ceramic, glass, and the like.

18. The method of claim 1 further including the step of depositing silver (Ag) on the AxSy film.

19. The method of claim 17 wherein the silver is deposited by sputtering or electrochemically and photodiffusion is used to integrate it into the film

20. The method of claim 1 further including the step of depositing silver (Ag) by adding a precursor of Ag.

21. The method of claim 1 further including the step of transferring the so produced films within a controlled environment to where Ag is deposited in a second deposition chamber

22. The method of claim 1 further including the step of growing a carbon based passivation film, after the growth of the AxSy film by utilizing the plasma to deposit a carbon based film.

23. The method of claim 1 further including the step of pulsing at least one of the precursor the plasma in alternating and cyclic modes.

24. A method of depositing A_{X}S_{Y}, where S is sulfur and X=0 to 1, Y=0 to 1 on a substrate comprising the steps of:
a) placing the substrate in a reactor chamber;
b) providing a precursor of A;
c) providing a precursor of S;
d) transporting the precursors of Ge, and S to the reactor chamber;
e) providing a plasma proximate to the substrate to enhance the deposition
e) heating the substrate so as to cause the precursors of A and S to deposit A and S on the surface of the substrate; and
f) pulsing at least one of the flow of the precursors of A and S and the plasma so as to form the desired AₓS_{y} film.

25. The method of claim 24 wherein A is at least one of Ge, Si, Cu, Zn, and Fe.

26. A method for growing a carbon based passivation film on a deposited film, comprising the steps of placing the deposited film in a reactor chamber after the growth of the film, providing a source of plasma and utilizing the plasma to deposit a carbon based film passivation film on the deposited film.
